(19) United States
(12) Patent Application Publication
(10) Pub. No.: US 2010/0123234 A1
(43) Pub. Date: May 20, 2010

(54) MULTI-CHIP PACKAGE AND MANUFACTURING METHOD THEREOF

(75) Inventor: Shih-Wen Chou, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignees: CHIPMOS TECHNOLOGIES INC., Hsinchu (TW); CHIPMOS TECHNOLOGIES (BERMUDA) LTD., Hamilton HM12 (BM)

(21) Appl. No.: 12/350,966

(22) Filed: Jan. 9, 2009

(30) Foreign Application Priority Data
Nov. 14, 2008 (TW) 97144169

(51) Int. Cl. H01L 23/00; H01L 21/50

(52) U.S. Cl. 257/686; 438/107; 257/E23.001; 257/E21.499; 438/118

(57) ABSTRACT

A multi-chip package includes a carrier, a first chip, a relay circuit substrate, a number of first bonding wires, a number of second bonding wires, a second chip, a number of third bonding wires, and an adhesive layer. The first chip is disposed on the carrier. The relay circuit substrate is disposed on the first chip. The first bonding wires are electrically connected between the first chip and the relay circuit substrate. The second bonding wires are electrically connected between the relay circuit substrate and the carrier. The second chip is disposed on the carrier and is stacked with the first chip. The third bonding wires are electrically connected between the second chip and the carrier. The adhesive layer is adhered between the first chip and the second chip. In addition, a manufacturing method of a multi-chip package is also provided.

### CROSS-REFERENCE TO RELATED APPLICATION

This application claims the priority benefit of Taiwan application serial no. 97144169, filed on Nov. 14, 2008. The entirety of the above-mentioned patent application is hereby incorporated by reference herein and made a part of specification.

### BACKGROUND OF THE INVENTION

1. Field of the Invention

The present invention relates generally to a semiconductor device and a manufacturing method thereof. More specifically, the present invention relates to a multi-chip package and a manufacturing method thereof.

2. Description of Related Art

In the semiconductor industry, production of integrated circuits (ICs) includes three stages: IC design, IC fabrication, and IC package.

During the IC fabrication, a chip is manufactured by performing steps of wafer fabrication, IC formation, wafer sawing, and so on. A wafer has an active surface, which generally refers to a surface equipped with active devices. After the ICs in the wafer are completed, a plurality of bonding pads are disposed on the active surface of the wafer, such that a chip formed by sawing the wafer can be externally electrically connected to a carrier through the bonding pads. The carrier is, for example, a leadframe or a package substrate. The chip can be connected to the carrier through conducting a wire-bonding technology or a flip-chip bonding technology, such that the bonding pads of the chip can be electrically connected to a plurality of bonding pads of the carrier to form a chip package.

Nonetheless, since the electrical industry currently intends to optimize electrical performance, reduce manufacturing costs, and achieve high integration of the ICs, the conventional chip package having a single chip is not able to satisfy said demands of the electrical industry. As such, two different solutions have been proposed by the electrical industry to meet the aforesaid demands. According to the first solution, all essential functions are integrated into the single chip. In other words, functions including digital logic, memories, and analogy are all integrated into the single chip which is in connection with the concept of system on chip (SOC). As such, in comparison with the conventional single chip, the SOC structure has more complicated functions. As for the second solution, a plurality of chips are packaged on a carrier by conducting the wire-bonding technology or the flip-chip bonding technology, so as to form a multi-chip package with integrated functions.

In the multi-chip package, taking a dynamic random access memory (DRAM) and a central processing unit (CPU) as examples, a plurality of DRAMs and CPUs can be packaged on the same substrate by means of a multi-chip module (MCM). Thereby, package density can be increased, package volume can be decreased, signal delay can be prevented, and high-speed operation can be accomplished. Hence, the multi-chip package is extensively applied to communication and portable electronic products.

Generally, when a central-pad design is adopted in the multi-chip package, the carrier must have an aperture that allows bonding wires to pierce through, such that the chips can be electrically connected to the carrier through the bonding wires. This results in reduction of areas on the carrier for disposing solder balls. Besides, in the multi-chip package, the farther the distance between the carrier and the bonding pads on the chip, the longer the bonding wires electrically connected between the carrier and the bonding pads. As a result, wire sweep risks are increased, and so is the entire thickness of the multi-chip package.

### SUMMARY OF THE INVENTION

The present invention is directed to a multi-chip package having a reduced entire thickness and an increased ball placement area.

The present invention is further directed to a manufacturing method of a multi-chip package. The manufacturing method is capable of forming the multi-chip package which has a reduced thickness and prevents occurrence of wire sweep risks.

The present invention is further directed to a manufacturing method of a multi-chip package, and the multi-chip package formed by performing the manufacturing method has sufficient ball placement area.

In the present invention, a multi-chip package including a carrier, a first chip, a relay circuit substrate, a plurality of first bonding wires, a plurality of second bonding wires, a second chip, a plurality of third bonding wires, and an adhesive layer is provided. The first chip is disposed on the carrier. The relay circuit substrate is disposed on the first chip. The first bonding wires are electrically connected between the first chip and the relay circuit substrate. The second bonding wires are electrically connected between the relay circuit substrate and the carrier. The second chip is disposed on the carrier and is stacked with the first chip. The third bonding wires are electrically connected between the second chip and the carrier. The first bonding wires, the second bonding wires, and the third bonding wires are located at the same side of the carrier. The adhesive layer is adhered between the first chip and the second chip.

According to an embodiment of the present invention, the carrier includes a circuit board or a leadframe.

According to an embodiment of the present invention, the first chip has a first active surface, a plurality of first bonding pads disposed on the first active surface, and a first back surface. The relay circuit substrate is disposed on the first active surface of the first chip and exposes the first bonding pads.

According to an embodiment of the present invention, the relay circuit substrate has an aperture exposing the first bonding pads. The first bonding wires are connected between the first bonding pads and the relay circuit substrate. Besides, the first bonding wires pierce the aperture.

According to an embodiment of the present invention, the relay circuit substrate has a notch exposing the first bonding pads. The first bonding wires are connected between the first bonding pads and the relay circuit substrate. In addition, the first bonding wires pierce the notch.

According to an embodiment of the present invention, the first chip is disposed between the carrier and the second chip. The adhesive layer covers the first chip, the relay circuit substrate, the first bonding wires, and an end of each of the second bonding wires. Said end of each of the second bonding wires is connected to the relay circuit substrate.

According to an embodiment of the present invention, a height of each of the third bonding wires is greater than a height of each of the second bonding wires, and the height of each of the second bonding wires is greater than a height of each of the first bonding wires.

According to an embodiment of the present invention, the second chip is disposed between the carrier and the first chip. The adhesive layer covers the second chip and an end of each of the third bonding wires. Said end of each of the third bonding wires is connected to the second chip.

According to an embodiment of the present invention, a height of each of the second bonding wires is greater than a height of each of the third bonding wires, and the height of each of the third bonding wires is greater than a height of each of the first bonding wires.

According to an embodiment of the present invention, the second chip has a second active surface, a plurality of second bonding pads disposed on the second active surface, and a second back surface. The adhesive layer is adhered between the second back surface and the first active surface.

According to an embodiment of the present invention, the third bonding wires are electrically connected between the second bonding pads and the carrier.

According to an embodiment of the present invention, the adhesive layer includes a B-staged adhesive layer.

According to an embodiment of the present invention, the multi-chip package further includes a molding compound disposed on the carrier. The molding compound encapsulates the first chip, the second chip, the second bonding wires, and the third bonding wires.

In the present invention, a manufacturing method of a multi-chip package is also provided. First, a carrier is provided. A first chip is disposed on the carrier, and a relay circuit substrate is disposed on the first chip. Next, a plurality of first bonding wires are formed, so as to electrically connect the first chip and the relay circuit substrate. A plurality of second bonding wires are then formed, so as to electrically connect the relay circuit substrate and the carrier. Thereafter, a second chip is adhered to the first chip through an adhesive layer. Here, the adhesive layer covers the first chip, the relay circuit substrate, the first bonding wires, and an end of each of the second bonding wires. Said end of each of the second bonding wires is connected to the relay circuit substrate. After that, a plurality of third bonding wires are formed, so as to electrically connect the second chip and the carrier.

According to an embodiment of the present invention, the adhesive layer is formed on a first active surface of the first chip.

According to an embodiment of the present invention, the adhesive layer is formed on a second back surface of the second chip, and the first bonding wires and the second bonding wires are able to pierce the adhesive layer.

According to an embodiment of the present invention, the adhesive layer includes a B-staged adhesive layer. Besides, a method of forming the B-staged adhesive layer includes forming a two-stage adhesive layer and B-stagizing the two-stage adhesive layer.

According to an embodiment of the present invention, the manufacturing method of the multi-chip package further includes performing a curing process to cure the B-staged adhesive layer.

In the present invention, a manufacturing method of a multi-chip package is further provided. First, a carrier is provided, and a second chip is disposed thereon. After that, a plurality of third bonding wires are formed, so as to electrically connect the second chip and the carrier. Thereafter, a first chip is adhered to the second chip through an adhesive layer, and a relay circuit substrate is disposed on the first chip. Next, a plurality of first bonding wires are formed, so as to electrically connect the first chip and the relay circuit substrate. A plurality of second bonding wires are then formed, so as to electrically connect the relay circuit substrate and the carrier.

According to an embodiment of the present invention, the adhesive layer is formed on a second active surface of the second chip.

According to an embodiment of the present invention, the adhesive layer is formed on a first back surface of the first chip.

According to an embodiment of the present invention, the adhesive layer includes a B-staged adhesive layer.

In the multi-chip package of the present invention, the relay circuit substrate is conducive to reduction of the height and the length of the bonding wires. Accordingly, the relay circuit substrate contributes to reducing the entire thickness of the multi-chip package and preventing wire sweep caused by the excessively long bonding wires.

In order to make the aforementioned and other features and advantages of the present invention more comprehensible, embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIGS. 1A to 1I are schematic cross-sectional views illustrating a manufacturing method of a multi-chip package according to an embodiment of the present invention.

FIGS. 2A and 2B are top views of FIG. 1B.

FIGS. 3A to 3F are schematic cross-sectional views illustrating a manufacturing method of a multi-chip package according to another embodiment of the present invention.

FIGS. 4A and 4B are top views of FIG. 3D.

### DESCRIPTION OF EMBODIMENTS

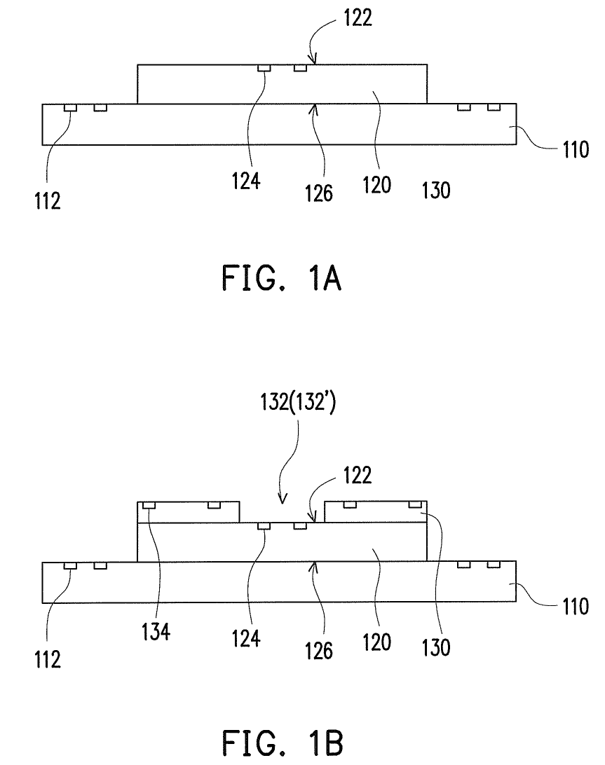

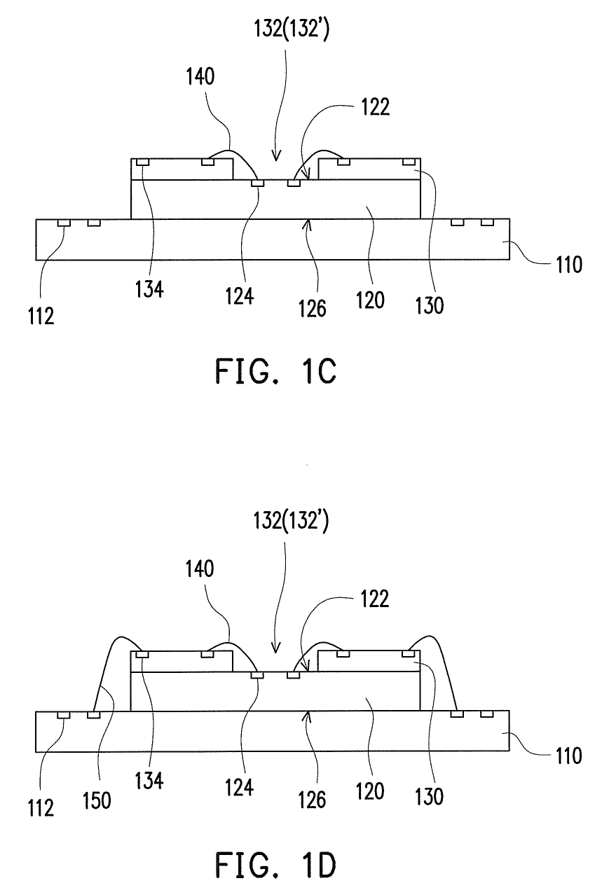

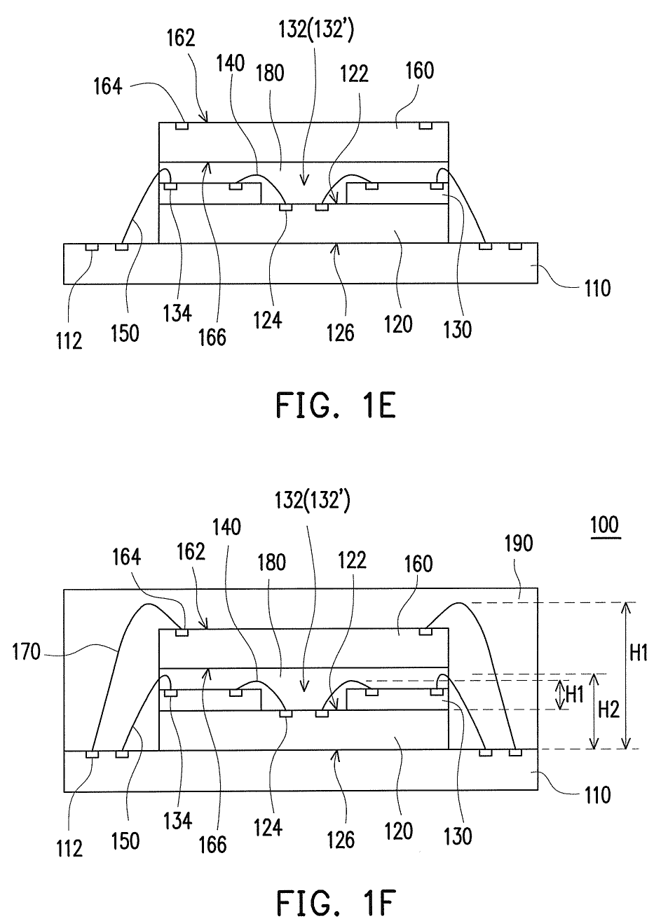

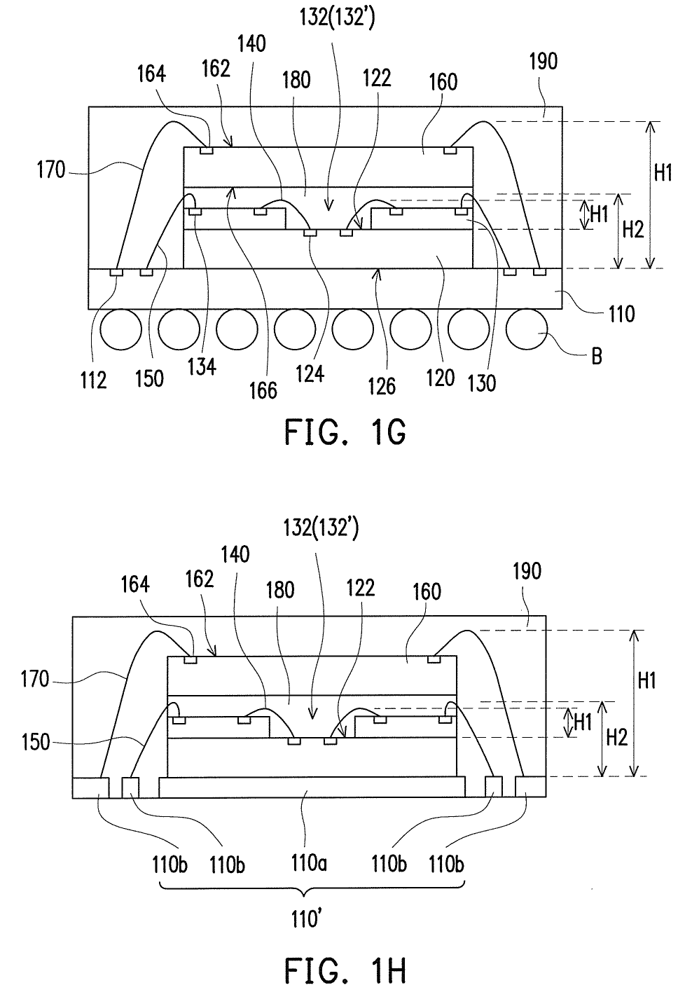

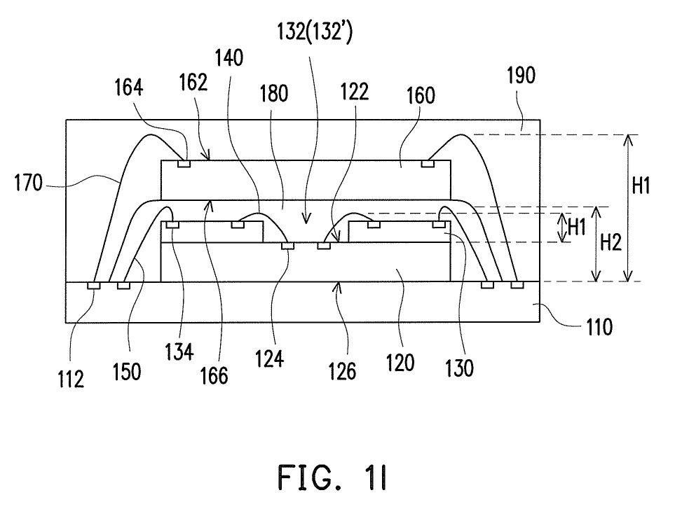

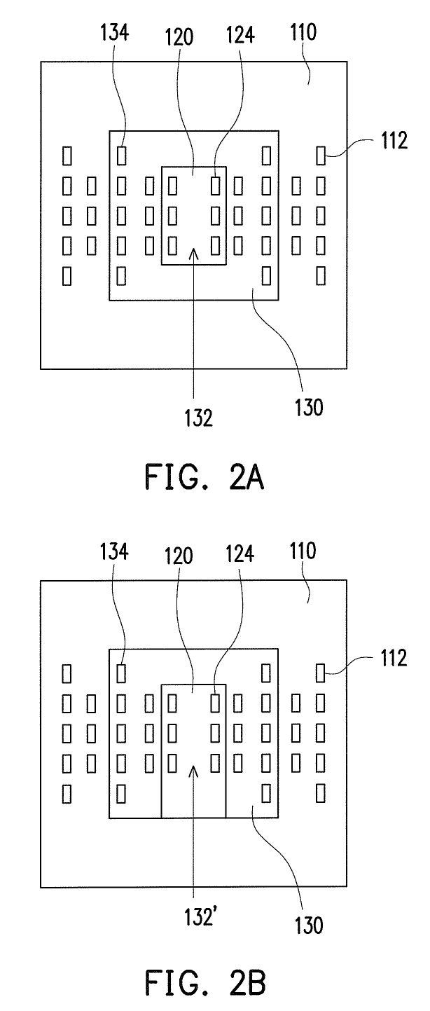

FIGS. 1A to 1I are schematic cross-sectional views illustrating a manufacturing method of a multi-chip package according to an embodiment of the present invention. FIGS. 2A and 2B are top views of FIG. 1B. First, referring to FIG. 1A, a carrier 110 is provided, and a first chip 120 having a first active surface 122, a plurality of first bonding pads 124 disposed on the first active surface 122, and a first back surface 126 is disposed on the carrier 110. In the present embodiment, the carrier 110 is a circuit board which can be a FR-4 circuit substrate, a FR-5 circuit substrate, a BT circuit substrate, or a PI circuit substrate. The carrier 110 can also be a leadframe which is made of copper or any other appropriate conductive material, for example. As shown in FIG. 1A, when the carrier 110 is a circuit board, the carrier 110 has a plurality of third bonding pads 112.

Next, referring to FIG. 1B, a relay circuit substrate 130 having an aperture 132 (as shown in FIG. 2A) or a notch 132′ (as shown in FIG. 2B) is disposed on the first chip 120. The relay circuit substrate 130 can be the FR-4 circuit substrate, the FR-5 circuit substrate, the BT circuit substrate, or the PI circuit substrate. As indicated in FIG. 1B, the aperture 132 or the notch 132′ of the relay circuit substrate 130 exposes the first bonding pads 124 of the first chip 120, such that subsequent wire bonding processes can be well performed. In the present embodiment, the relay circuit substrate 130 has a plurality of fourth bonding pads 134, and all of the fourth bonding pads 134 are disposed on a surface that is not connected to the first chip 120.

After that, referring to FIG. 1C, a plurality of first bonding wires 140 are formed to electrically connect the first chip 120 and the relay circuit substrate 130. The first bonding wires 140 pierce the aperture 132 or the notch 132′ and are respectively connected between the first bonding pads 124 and the fourth bonding pads 134. In the present embodiment, the first bonding wires 140 are, for example, gold wires. Besides, the first bonding wires 140 are formed by using a wire bonder, for example.

Referring to FIG. 1D, a plurality of second bonding wires 150 respectively connected between the first bonding pads 124 and the third bonding pads 112 are then formed, so as to electrically connect the relay circuit substrate 130 and the carrier 110. In the present embodiment, the second bonding wires 150 are, for example, gold wires. Besides, the second bonding wires 150 are formed by using a wire bonder, for example. As clearly shown in FIG. 1D, the first chip 120 is electrically connected to the carrier 110 through the first bonding wires 140, the second bonding wires 150, and the relay circuit substrate 130. Through the disposition of the relay circuit substrate 130, the length and the height of the first bonding wires 140 and those of the second bonding wires 150 in the present embodiment can be reduced notably, which is greatly conducive to improvement of electrical performance of electronic devices, decrease in manufacturing costs, and reduction of the thickness of the multi-chip package.

Next, referring to FIG. 1E, a second chip 160 is adhered to the first chip 120 through an adhesive layer 180. The second chip 160 has a second active surface 162, a plurality of second bonding pads 164 disposed on the second active surface 162, and a second back surface 166. The adhesive layer 180 covers the first chip 120, the relay circuit substrate 130, the first bonding wires 140, and an end of each of the second bonding wires 150. Said end of each of the second bonding wires 150 is connected to the relay circuit substrate 130. According to the present embodiment, the adhesive layer 180 not only can serve as an adhesive but also can support the second chip 120 as well as protect the first bonding wires 140 and the second bonding wires 150.

In the present embodiment, the adhesive layer 180 is, for example, formed by printing, coating, and so on. Note that the adhesive layer 180 allows the first bonding wires 140 and the second bonding wires 150 to be disposed therein, so as to protect the first and the second bonding wires 140 and 150. In a preferred embodiment, the adhesive layer 180 is, for example, a B-staged adhesive layer which is formed by first forming a two-stage adhesive layer and B-stagizing the same by heating or light irradiation (e.g. ultraviolet light irradiation), for example.

In the present embodiment, the adhesive layer 180 can be formed on the first active surface 122 of the first chip 120 or on the second back surface 166 of the second chip 160. In the process of bonding the first chip 120 to the second chip 160, the first bonding wires 140 and the second bonding wires 150 are positioned in the adhesive layer 180. Specifically, when the adhesive layer 180 is formed on the first active surface 122 of the first chip 120, the first bonding wires 140 and the second bonding wires 150 are encapsulated by the adhesive layer 180 during the formation thereof. Given that the adhesive layer 180 is formed on the second back surface 166 of the second chip 160, the first bonding wires 140 and the second bonding wires 150 are cured into the adhesive layer 180 in the process of disposing the second chip 160 and the adhesive layer 180 on the first chip 120.

According to the present embodiment, after the second chip 160 is disposed on the first chip 120 or after a molding compound 190 covers the first chip 120 and the second ship 160, the B-staged adhesive layer is cured. If it is deemed necessary, a curing process can be further performed to cure the B-staged adhesive layer.

Note that the B-staged adhesive layer can be model no. 8008 or model no. 8008HT supplied by ABLESTIK, for example. In addition, the B-staged adhesive layer can also be model no. 6200, model no. 6201, model no. 6202C (all provided by ABLESTIK), model no. SA-200-6 or model no SA-200-10 (both provided by HITACHI Chemical CO., Ltd.), for example. However, the B-staged adhesive layer is not limited to what was disclosed above according to the present invention. Namely, the B-staged adhesive layer can also be an adhesive material having B-staged properties.

Finally, referring to FIG. 1F, a plurality of third bonding wires 170 respectively connected between the second bonding pads 164 and the third bonding pads 112 are formed, so as to electrically connect the second chip 160 and the carrier 110. A molding compound 190 is then formed to encapsulate the first chip 120, the second chip 160, the second bonding wires 150, and the third bonding wires 170. In the present embodiment, the molding compound 190 is, for example, made of epoxy resin or any other appropriate material.

A multi-chip package of the present embodiment is described below with reference to FIG. 1F.

As indicated in FIG. 1F, the multi-chip package 100 of the present embodiment includes a carrier 110, a first chip 120, a relay circuit substrate 130, a plurality of first bonding wires 140, a plurality of second bonding wires 150, a second chip 160, a plurality of third bonding wires 170, and an adhesive layer 180. The first chip 120 is disposed on the carrier 110. The relay circuit substrate 130 is disposed on the first chip 120. The first bonding wires 140 are electrically connected between the first chip 120 and the relay circuit substrate 130. The second bonding wires 150 are electrically connected between the relay circuit substrate 130 and the carrier 110. The second chip 160 is disposed on the carrier 110 and is stacked with the first chip 120. The third bonding wires 170 are electrically connected between the second chip 160 and the carrier 110. The first bonding wires 140, the second bonding wires 150, and the third bonding wires 170 are located at the same side of the carrier 110. The adhesive layer 180 is adhered between the first chip 120 and the second chip 160.

As shown in FIG. 1F, a height H1 of each of the third bonding wires 170 is greater than a height H2 of each of the second bonding wires 150, and the height H2 of each of the second bonding wires 150 is greater than a height H3 of each of the first bonding wires 140.

It should be noted that in FIG. 1G the carrier 110 has no aperture allowing the bonding wires to pierce through, and therefore the carrier 110 has a larger accommodation area for disposing more solder balls B.

Referring to FIG. 1H, in the present embodiment, a carrier 110′ can also be a leadframe and includes a die pad 110a and a plurality of leads 110b. Besides, referring to FIG. 1I, in the present embodiment, the adhesive layer 180 can extend to the carrier 110 and completely encapsulate the second bonding wires 150.

Additionally, in another embodiment which is not depicted in the drawings, the relay circuit substrate can also be formed by two individual silicon chips or two individual circuit substrates respectively disposed at two sides of the first bonding pads 124, such that the relay circuit substrate can have the same connection correlation as that of the relay circuit substrate 130 depicted in FIG. 1F.

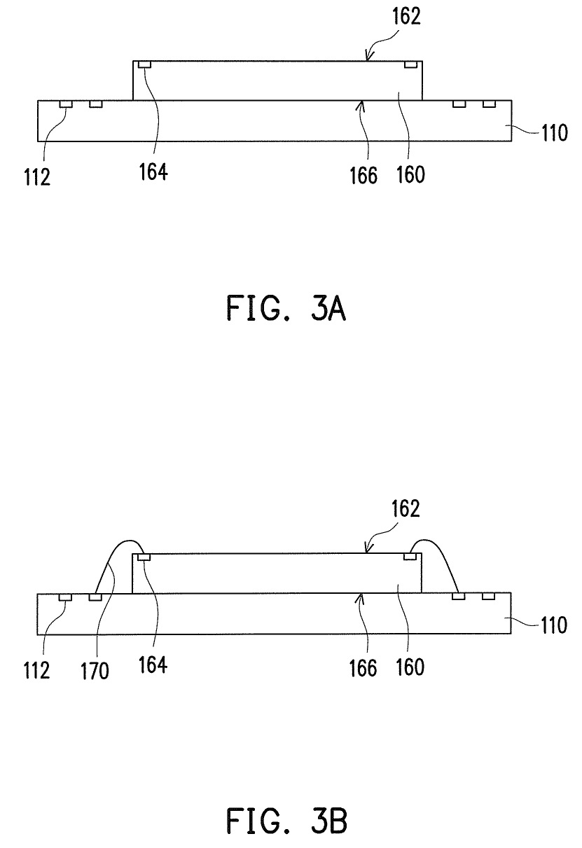

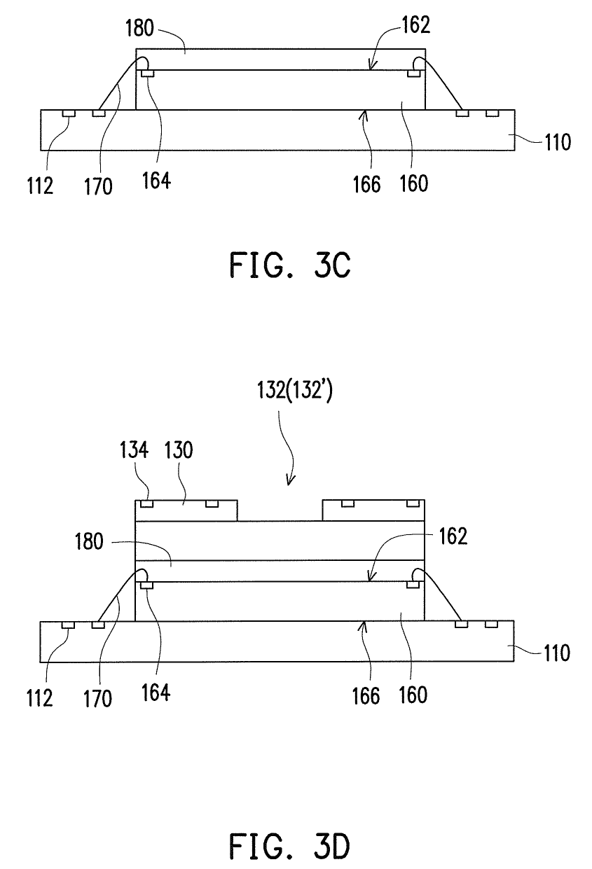

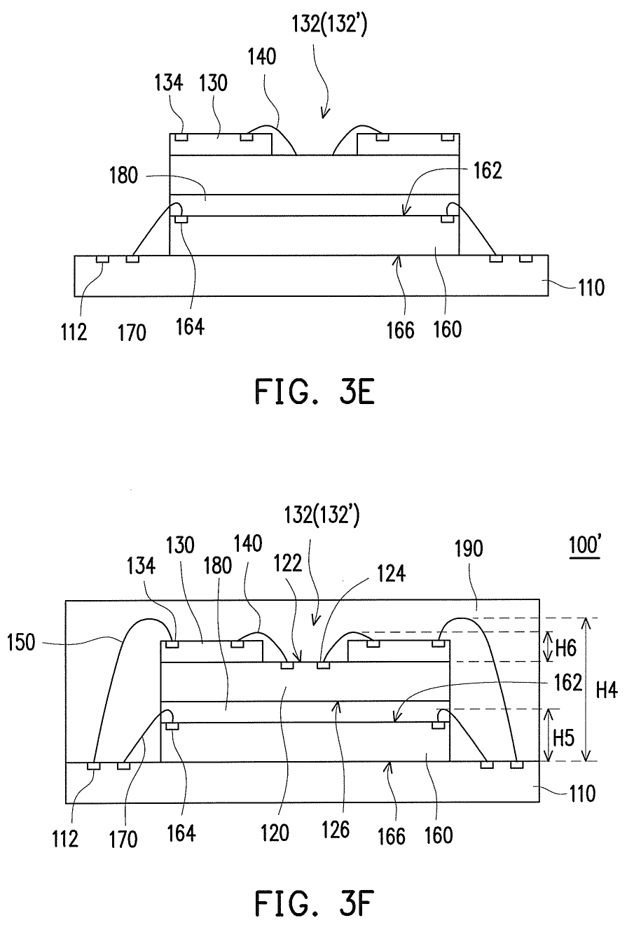

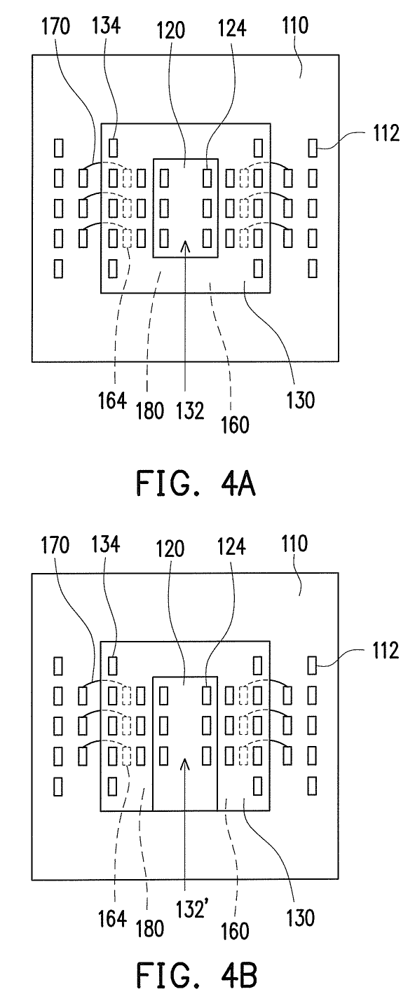

FIGS. 3A to 3F are schematic cross-sectional views illustrating a manufacturing method of a multi-chip package according to another embodiment of the present invention, and FIGS. 4A and 4B are top views of FIG. 3D.

First, referring to FIG. 3A, a carrier 110 is provided, and a second chip 160 having a second active surface 162, a plurality of second bonding pads 164 disposed on the second active surface 162, and a second back surface 166 is disposed on the carrier 110. In the present embodiment, the carrier 110 is a circuit board which can be a FR-4 circuit substrate, a FR-5 circuit substrate, a BT circuit substrate, or a PI circuit substrate. Certainly, the carrier 110 can also be a leadframe in other embodiments of the present invention, and the leadframe is made of copper or any other appropriate conductive material, for example. As shown in FIG. 1A, when the carrier 110 is a circuit board, the carrier 110 has a plurality of third bonding pads 112.

Next, referring to FIG. 3B, a plurality of third bonding wires 170 respectively connected between the second bonding pads 164 and the third bonding pads 112 are formed, so as to electrically connect the second chip 160 and the carrier 110. In the present embodiment, the third bonding wires 170 are, for example, gold wires. Besides, the third bonding wires 170 are formed by using a wire bonder, for example.

Thereafter, referring to FIG. 3C, a first chip 120 is adhered to the second chip 160. The first chip 120 has a first active surface 122, a plurality of first bonding pads 124 disposed on the first active surface 122, and a first back surface 126. According to the present embodiment, the adhesive layer 180 not only can serve as an adhesive but also can support the first chip 120 as well as protect the third bonding wires 170.

In the present embodiment, the adhesive layer 180 can be formed on the first back surface 126 of the first chip 120 or on the second active surface 162 of the second chip 160. The adhesive layer 180 is, for example, formed by printing, coating, and so on. Note that the adhesive layer 180 permits the third bonding wires 170 to sink therein, so as to protect the third bonding wires 170. In a preferred embodiment, the adhesive layer 180 is, for example, a B-staged adhesive layer which is formed by first forming a two-stage adhesive layer and B-stagizing the same by heating or light irradiation (e.g. ultraviolet light irradiation), for example. In the process of bonding the second chip 160 to the first chip 120, the third bonding wires 170 are cured into the B-staged adhesive layer.

According to the present embodiment, after the first chip 120 is disposed on the second chip 160 or after a molding compound 190 covers the first chip 120 and the second ship 160, the B-staged adhesive layer is cured. If it is deemed necessary, a curing process can be further performed to cure the B-staged adhesive layer.

Note that the B-staged adhesive layer can be model No. 8008 or model No. 8008HT supplied by ABLESTIK. In addition, the B-staged adhesive layer can also be model no. 6200, model no. 6201, model no. 6202C (all provided by ABLESTIK), model no. SA-200-6 or model no SA-200-10 (both provided by HITACHI Chemical CO., Ltd.), for example. However, the B-staged adhesive layer is not limited to what was disclosed above in the present invention. Namely, the B-staged adhesive layer can also be an adhesive material having B-staged properties.

Next, referring to FIG. 3D, a relay circuit substrate 130 having an aperture 132 (as shown in FIG. 4A) or a notch 132′ (as shown in FIG. 4B) is disposed on the first chip 120. The relay circuit substrate 130 can be the FR-4 circuit substrate, the FR-5 circuit substrate, the BT circuit substrate, or the PI circuit substrate. As indicated in FIG. 3D, the aperture 132 or the notch 132′ of the relay circuit substrate 130 exposes the first bonding pads 124 of the first chip 120, such that subsequent wire bonding processes can be well performed. In the present embodiment, the relay circuit substrate 130 has a plurality of fourth bonding pads 134, and all of the fourth bonding pads 134 are disposed on a surface that is not connected to the adhesion layer 180.

After that, referring to FIG. 3E, a plurality of first bonding wires 140 are formed to electrically connect the first chip 120 and the relay circuit substrate 130. The first bonding wires 140 pierce the aperture 132 or the notch 132′ and are respectively connected between the first bonding pads 124 and the fourth bonding pads 134. In the present embodiment, the first bonding wires 140 are, for example, gold wires. Besides, the first bonding wires 140 are formed by using a wire bonder, for example.

Referring to FIG. 3F, a plurality of second bonding wires 150 respectively connected between the first bonding pads 124 and the third bonding pads 112 are then formed, so as to electrically connect the relay circuit substrate 130 and the carrier 110. After that, a molding compound 190 is formed to encapsulate the first chip 120, the second chip 160, the second bonding wires 150, and the third bonding wires 170. In the present embodiment, the molding compound 190 is, for example, made of epoxy resin or any other appropriate material.

As clearly shown in FIG. 3F, the first chip 120 is electrically connected to the carrier 110 through the first bonding wires 140, the second bonding wires 150, and the relay circuit substrate 130. Through the disposition of the relay circuit substrate 130, the length and the height of the first bonding wires 140 and those of the second bonding wires 150 in the present embodiment can be reduced notably, which is greatly conducive to improvement of electrical performance of electronic devices, decrease in manufacturing costs, and reduction of the thickness of the multi-chip package.

Another multi-chip package of the present embodiment is described below with reference to FIG. 3F.

Referring to FIG. 3F, in comparison with the multi-chip package 100 depicted in FIG. 1F, the multi-chip package 100′ of the present embodiment has a second chip 160 disposed between a carrier 110 and a first chip 120. An adhesive layer 180 covers the second chip 160 and an end of each of the third bonding wires 170 connected to the second chip 160.

As shown in FIG. 3F, a height H4 of each of the second bonding wires 150 is greater than a height H5 of each of the third bonding wires 170, and the height H5 of each of the third bonding wires 170 is greater than a height H6 of each of the first bonding wires 140.

In light of the foregoing, the adhesive layer allowing the bonding wires to pierce through is disposed among the chips in the multi-chip package of the present invention. Thereby, there exists sufficient space permitting the bonding wires to extend. The carrier can be electrically connected to the chips through the bonding wires without being equipped with the aperture that allows the bonding wires to pierce through. Accordingly, the carrier has a larger accommodation area for disposing more solder balls. Besides, the adhesive layer has the function of supporting the chip and protecting the bonding wires. Moreover, the relay circuit substrate disposed on the chips results in reduction of the required length and height of the bonding wires, and the entire thickness of the multi-chip package can be further decreased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A multi-chip package, comprising:
a carrier;
a first chip, disposed on the carrier;
a relay circuit substrate, disposed on the first chip;
a plurality of first bonding wires, electrically connected between the first chip and the relay circuit substrate;
a plurality of second bonding wires, electrically connected between the relay circuit substrate and the carrier;
a second chip, disposed on the carrier and stacked with the first chip;
a plurality of third bonding wires, electrically connected between the second chip and the carrier, wherein the plurality of first bonding wires, the plurality of second bonding wires, and the plurality of third bonding wires are disposed at the same side of the carrier; and
an adhesive layer, adhered between the first chip and the second chip.

2. The multi-chip package as claimed in claim 1, wherein the carrier includes a circuit board or a leadframe.

3. The multi-chip package as claimed in claim 1, wherein the first chip has a first active surface, a plurality of first bonding pads disposed on the first active surface, and a first back surface, and the relay circuit substrate is disposed on the first active surface of the first chip and exposes the plurality of first bonding pads.

4. The multi-chip package as claimed in claim 3, wherein the relay circuit substrate has an aperture exposing the plurality of first bonding pads, the plurality of first bonding wires being connected between the plurality of first bonding pads and the relay circuit substrate and piercing the aperture.

5. The multi-chip package as claimed in claim 3, wherein the relay circuit substrate has a notch exposing the plurality of first bonding pads, the plurality of first bonding wires being connected between the plurality of first bonding pads and the relay circuit substrate and piercing the notch.

6. The multi-chip package as claimed in claim 1, wherein the first chip is disposed between the carrier and the second chip, and the adhesive layer covers the first chip, the relay circuit substrate, the plurality of first bonding wires, and an end of each of the plurality of second bonding wires connected to the relay circuit substrate.

7. The multi-chip package as claimed in claim 6, wherein a height of each of the plurality of third bonding wires is greater than a height of each of the plurality of second bonding wires, and the height of each of the plurality of second bonding wires is greater than a height of each of the plurality of first bonding wires.

8. The multi-chip package as claimed in claim 1, wherein the second chip is disposed between the carrier and the first chip, and the adhesive layer covers the second chip and an end of each of the plurality of third bonding wires connected to the second chip.

9. The multi-chip package as claimed in claim 8, wherein a height of each of the plurality of second bonding wires is greater than a height of each of the plurality of third bonding wires, and the height of each of the plurality of third bonding wires is greater than a height of each of the plurality of first bonding wires.

10. The multi-chip package as claimed in claim 1, wherein the second chip has a second active surface, a plurality of second bonding pads disposed on the second active surface, and a second back surface, and the adhesive layer is adhered between the second back surface and the first active surface.

11. The multi-chip package as claimed in claim 10, wherein the plurality of third bonding wires are electrically connected between the plurality of second bonding pads and the carrier.

12. The multi-chip package as claimed in claim 1, wherein the adhesive layer comprises a B-staged adhesive layer.

13. The multi-chip package as claimed in claim 1, further comprising a molding compound disposed on the carrier, wherein the molding compound encapsulates the first chip, the second chip, the plurality of second bonding wires, and the plurality of third bonding wires.

14. A manufacturing method of a multi-chip package, comprising:
providing a carrier;
disposing a first chip on the carrier;
disposing a relay circuit substrate on the first chip;
forming a plurality of first bonding wires electrically connected between the first chip and the relay circuit substrate;
forming a plurality of second bonding wires electrically connected between the relay circuit substrate and the carrier;
adhering a second chip to the first chip through an adhesive layer, wherein the adhesive layer covers the first chip, the relay circuit substrate, the plurality of first bonding wires, and an end of each of the plurality of second bonding wires connected to the relay circuit substrate; and
forming a plurality of third bonding wires electrically connected between the second chip and the carrier.

15. The manufacturing method of the multi-chip package as claimed in claim 14, wherein the adhesive layer is formed on a first active surface of the first chip.

16. The manufacturing method of the multi-chip package as claimed in claim 14, wherein the adhesive layer is formed on a second back surface of the second chip, and the plurality of first bonding wires and the plurality of second bonding wires are able to pierce the adhesive layer.

17. The manufacturing method of the multi-chip package as claimed in claim 14, wherein the adhesive layer comprises a B-staged adhesive layer, and a method of forming the B-staged adhesive layer comprises:
forming a two-stage adhesive layer on a second back surface of the second chip; and
B-stagizing the two-stage adhesive layer to form the B-staged adhesive layer.

18. The manufacturing method of the multi-chip package as claimed in claim 17, further comprising:
performing a curing process to cure the B-staged adhesive layer.

19. A manufacturing method of a multi-chip package, comprising:
providing a carrier;
disposing a second chip on the carrier;
forming a plurality of third bonding wires electrically connected between the second chip and the carrier;
adhering a first chip to the second chip through an adhesive layer;
disposing a relay circuit substrate on the first chip;
forming a plurality of first bonding wires electrically connected between the first chip and the relay circuit substrate; and
forming a plurality of second bonding wires electrically connected between the relay circuit substrate and the carrier.

20. The manufacturing method of the multi-chip package as claimed in claim 19, wherein the adhesive layer is formed on a second active surface of the second chip.

21. The manufacturing method of the multi-chip package as claimed in claim 19, wherein the adhesive layer is formed on a first back surface of the first chip.

22. The manufacturing method of the multi-chip package as claimed in claim 19, wherein the adhesive layer comprises a B-staged adhesive layer.
